(19) United States
(12) Patent Application Publication
(10) Pub. No.: US 2009/0140339 A1
(43) Pub. Date: Jun. 4, 2009

(54) ESD Protection Device and Method for Manufacturing the Same

(76) Inventor: San Hong Kim, Bucheon-si (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/259,580

(22) Filed: Oct. 28, 2008

(30) Foreign Application Priority Data
Nov. 30, 2007 (KR) 10-2007-0123254

(51) Int. Cl. H01L 23/62; H01L 21/336

(52) U.S. Cl. 257/355; 438/289; 257/E21.409; 257/E23.001

(57) ABSTRACT

Disclosed is an electro-static discharge protection device. The electro-static discharge protection device can include a second conductive type epitaxial layer on a substrate; a second conductive type well on a first region above the second conductive type epitaxial layer; a first conductive type deep well in the second conductive type epitaxial layer between the second conductive type epitaxial layer and the second conductive type well; a plurality of active regions defined by a plurality of isolation layers above the second conductive type epitaxial layer; and a transistor and an ion implantation region in the active regions.

### CROSS-REFERENCE TO RELATED APPLICATION

The present application claims the benefit under 35 U.S.C. §119 of Korean Patent Application No. 10-2007-0123254, filed Nov. 30, 2007, which is hereby incorporated by reference in its entirety.

### BACKGROUND

To improve properties of a light receiving unit, CIS (CMOS image sensor) technology typically uses a heavily doped epitaxial layer as compared with conventional logic technology. Accordingly, the epitaxial layer has doping concentration higher than that of a P-well, so that the epitaxial layer has resistance lower than that of the P-well. Therefore, resistance of the epitaxial layer serving as a base area becomes lower than resistance of an epitaxial layer obtained from the conventional logic technology.

The reduced base resistance created by the CIS technology may cause non-uniform turn-on of an electro-static discharge (ESD) device having a multi-finger structure, degrading the entire ESD performance.

FIG. 1 is a graph illustrating an It2 (thermal runaway current) value to the number of fingers of a device used as an ESD protection device in 0.13 μm logic compared to a device used as an ESD protection device in 0.13 μm CIS. As illustrated by FIG. 1, the It2 value decreases as the number of fingers of a multi-finger structure increases for the ESD device in a CIS process.

According to the related art, as the size of a photodiode is scaled down, the thickness of an epitaxial layer is also reduced. In the case of using a heavily doped substrate and a high temperature silicon epitaxial process employed in a conventional CIS process, out-diffusion of P type ions (e.g. boron ions) may also occur.

FIG. 2 is a graph illustrating a profile of doping concentration (Y axis) in a depth direction (X axis) of an epitaxial layer.

Referring to FIG. 2, L represents a doping concentration profile in a general logic device and the 3 μm, 4 μm, and 7 μm arrows indicate the doping concentration profile for a CIS device where the epitaxial layer on the p-substrate has a thickness of 3 μm, 4 μm, and 7 μm, respectively.

In the general logic device, the substrate has concentration lower than that of a P-well.

Meanwhile, in the case of a CIS device using an epitaxial layer, when the epitaxial layer has a thickness of about 7 μm, the epitaxial layer adjacent to a P-well has concentration lower than that of the P-well, which is similar to the logic device.

However, when the epitaxial layer has a thickness of about 4 μm, out-diffusion occurs in the region of the epitaxial layer adjacent to the P-well, so that the epitaxial layer has concentration similar to that of the P-well. Further, when the epitaxial layer has a thickness of about 3 μm, the out-diffusion frequently occurs in the region of the epitaxial layer adjacent to the P-well, so that the epitaxial layer has concentration higher than that of the P-well. Thus, resistance of the epitaxial layer serving as a base area becomes lower than resistance of an epitaxial layer obtained from the conventional logic technology.

As described above, the reduced base resistance may cause non-uniform turn-on of an ESD device having a multi-finger structure, degrading the entire ESD performance.

### BRIEF SUMMARY

Embodiments of the present invention relate to an electro-static discharge (ESD) protection device and a method for manufacturing the same.

When the conventional CIS process uses an epitaxial layer having a thickness of about 6 μm or more, it is possible to obtain properties similar to properties obtained from the conventional logic process. However, when an epitaxial layer having a thickness of about 4 μm or less is used in the conventional CIS process, performance of an ESD protection device may be degraded. Accordingly, embodiments of the present invention provide an ESD protection device capable of reducing or inhibiting deterioration of ESD properties and a method for manufacturing the same.

An electro-static discharge protection device according to an embodiment includes a second conductive type epitaxial layer on a substrate, a second conductive type well on a first region above the second conductive type epitaxial layer, a first conductive type deep well between the second conductive type epitaxial layer and the second conductive type well, a plurality of active regions defined by a plurality of isolation layers above the second conductive type epitaxial layer, and a transistor and an ion implantation region in the active regions.

A method for manufacturing an electro-static discharge protection device according to another embodiment includes forming a second conductive type epitaxial layer on a substrate, forming a second conductive type well on a first region above the second conductive type epitaxial layer, forming a first conductive type deep well between the second conductive type epitaxial layer and the second conductive type well, defining a plurality of active regions by forming a plurality of isolation layers above the second conductive type epitaxial layer, and forming a transistor in the active region.

### BRIEF DESCRIPTION OF THE DRAWINGS

FIGS. 1 and 2 are plots illustrating problems of an ESD protection device according to the related art.

FIG. 3 is a cross-sectional view of an ESD protection device according to an embodiment of the present invention.

FIG. 4 is a plot illustrating an effect of an ESD protection device according to an embodiment of the present invention.

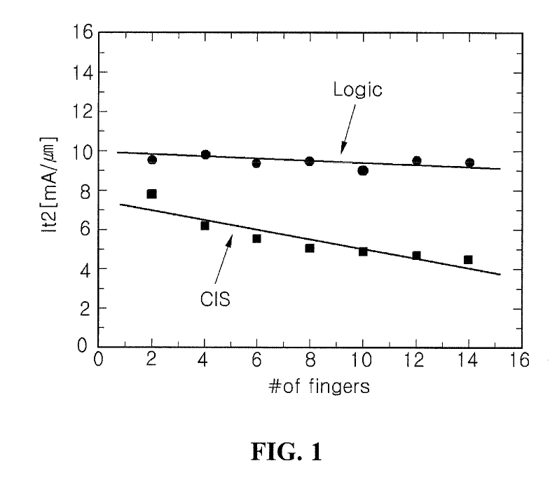

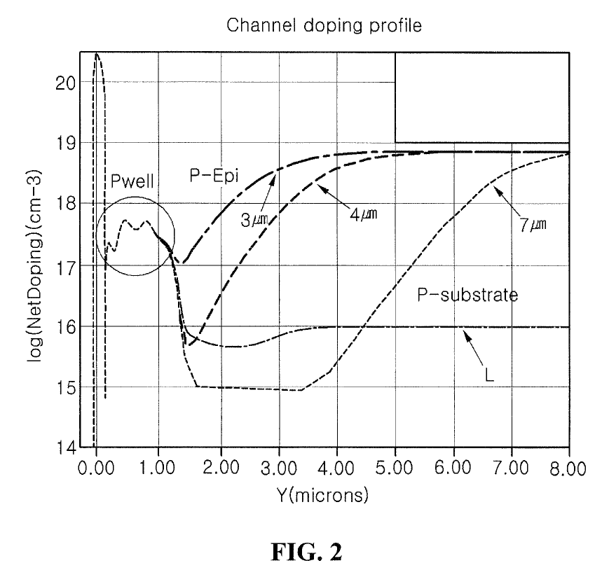

### DETAILED DESCRIPTION

Hereinafter, embodiments of an ESD protection device and a method for manufacturing the same will be described with reference to the accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present.

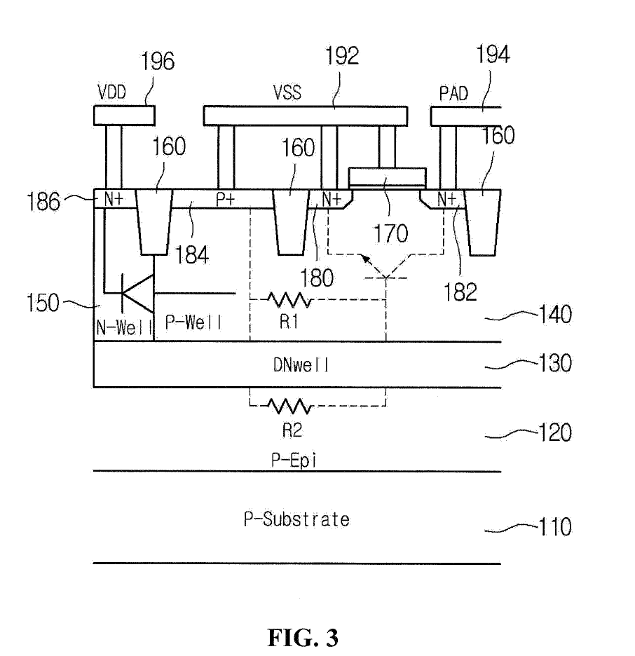

FIG. 3 shows a cross-sectional view of an ESD protection device according to an embodiment of the present invention. The subject ESD device can be fabricated in a CIS process.

An ESD protection device according to an embodiment can include a second conductive type epitaxial layer 120 on a substrate 110, a second conductive type well (e.g., a P-Well) 140 on a first region above the second conductive type epitaxial layer 120, a first conductive type deep well (e.g., a DNWell) 130 between the second conductive type epitaxial layer 120 and the second conductive type well 140, a plurality of active regions defined by a plurality of isolation layers 160 above the second conductive type epitaxial layer 120, and a transistor 170 and ion implantation regions 180, 182, and 184 formed in the active regions. The transistor 170 can include a gate electrode connected to a VSS line 192 and the ion implantation regions 180 and 182 (source/drain regions). One ion implantation region 180 can be connected to the VSS line 192 and the other ion implantation region 182 can be connected to a pad line 194. The third ion implantation region 184 can be formed separated from the transistor 170 by the isolation layer 160 while being connected to the VSS line 192. The ion implantation regions 180 and 182 of the transistor 170 can be first conductive type regions while the third ion implantation region 184 can be a second conductive type region.

In a further embodiment, the ESD device can include a first conductive type well 150 formed on a second region above the second conductive type epitaxial layer 120 while being aligned horizontally to the second conductive type well 140, and a fourth ion implantation region 186 formed on the first conductive type well 150. The fourth ion implantation region 186 in the first conductive type well 150 can be connected with a VDD line 196.

According to an embodiment, the second conductive type epitaxial layer 120 can have a thickness of about 4 μm (or less) and the first conductive type deep well 130 can be formed with a thickness of about 1 μm to about 2 μm in the second conductive type epitaxial layer 120.

Further, the first conductive type deep well 130 can have a concentration of first conductive type impurities of about 1×10⁷/cm³ to about 1×10¹⁸/cm³.

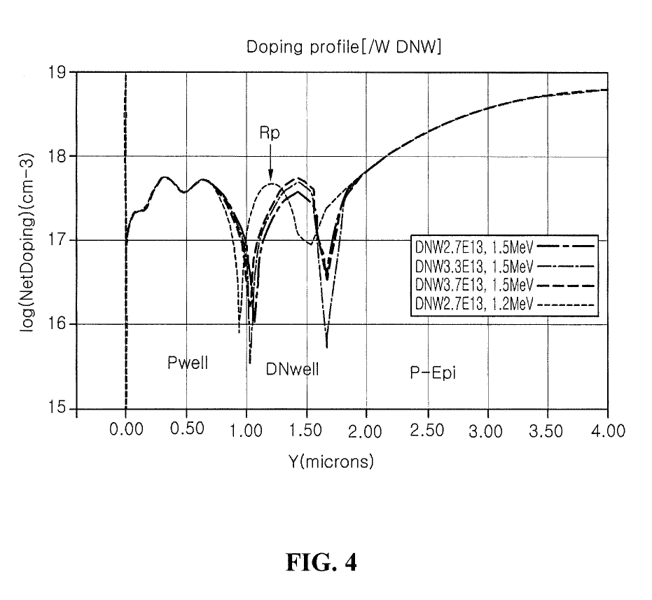

FIG. 4 is a graph illustrating an effect of the ESD protection device according to the embodiment. In particular, the first deep conductive type well 130 can be disposed between the second conductive type epitaxial layer 120 and the second conductive type well 140, so that the second conductive type well 140 can be electrically isolated from the P-substrate 110.

As illustrated in FIG. 4, the first conductive type deep well 130 can have a thickness of about 1 μm to about 2 μm with the central value Rp of doping at about 1 μm to about 2 μm. This value is larger than a typical junction depth (about 1 μm to about 2 μm) of a P-Well.

Thus, the first conductive type deep well 130 is formed between the second conductive type epitaxial layer 120 and the second conductive type well 140 so that the second conductive type well 140 can be electrically isolated from the P-substrate 110.

According to the ESD protection device of an embodiment, a part used as the ESD device is electrically isolated, so that performance of the NPN device (see transistor symbol of FIG. 3) can be inhibited from being degraded by reduction of base resistance.

Further, according to an embodiment, the first conductive type deep well 130 is connected with the VDD terminal, so that a parasitic diode (see diode symbol of FIG. 3) is formed between a pad and the VDD terminal. Thus, the parasitic diode has Ron characteristics superior to those of a P+/Nwell parasitic diode included in the conventional PMOS device, so that ESD properties can be improved.

Hereinafter, a method for manufacturing the ESD protection device according to an embodiment will be described with reference to FIG. 3.

First, a second conductive type epitaxial layer 120 can be formed on a substrate 110. The substrate 110 can be doped with second conductive type dopant. For example, a P type epitaxial layer 120 can be formed on a P type substrate 110. According to certain embodiments, the epitaxial layer 120 can be formed to have a thickness of about 4 μm or less.

Next, a second conductive type well 140 can be formed on a first region above the second conductive type epitaxial layer 120. For example, group III ions can be implanted into the P type epitaxial layer 120 to form the P type well 140. At this time, the second conductive type well 140 can have doping concentration of about 1×10¹⁷/cm³ to about 1×10¹⁸/cm³.

Then, a first conductive type deep well 130 can be formed at a boundary between the second conductive type epitaxial layer 120 and the second conductive type well 140. In another embodiment, the first conductive type deep well 130 can be formed before forming the second conductive type well 140.

According to an embodiment, a ‘resistor’ R1 of the second conductive type well 140 is electrically isolated from a ‘resistor’ R2 of the second conductive type epitaxial layer 120 by the first conductive type deep well 130, so that the ‘resistor’ R1 identical to that in the conventional logic process can be obtained. Thus, non-uniform triggering in the multi-finger structure can be inhibited from occurring.

Hereinafter, a process of forming the first conductive type deep well 130 will be described.

According to an embodiment, when the second conductive type epitaxial layer 120 has a thickness of about 4 μm or less, the first conductive type deep well 130 can be formed in the second conductive type epitaxial layer 120 to have a thickness of about 1 μm to about 2 μm.

For example, phosphorus (P) can be implanted into the second conductive type epitaxial layer 120 with energy of about 1.0 MeV to about 2.0 MeV, so that the first conductive type deep well 130 having a thickness of about 1 μm to about 2 μm can be formed. When the doping energy is about 1.0 MeV to about 2.0 MeV, the central value Rp of doping can be about 1.0 μm to about 2.0 μm from the surface of the second conductive type epitaxial layer 120.

Meanwhile, in the step of forming the first conductive type deep well 130, the implant dose can have a value of about 1.0×10¹³/cm² to about 5×10¹³/cm² to form the first conductive type deep well 130 with a concentration of about 1×10¹⁷/cm³ to about 1×10¹⁸/cm³. However, according to an embodiment, the amount of implanted ions can be determined as described above such that the first conductive type deep well 130 has a concentration of about 1×10¹⁷/cm³ to about 1×10¹⁸/cm³ for electrical isolation.

Next, isolation layers 160 can be formed in the second conductive type well 140 to define the active regions.

Then, a transistor 170 and ion implantation regions can be formed in the active region. For example, a source region 180 and a drain region 182 can be formed by implanting first conductive type ions into the substrate, and a second conductive type ion implantation region 184 can be formed by implanting second conductive type ions into the substrate.

According to a further embodiment, a first conductive type well 150 can be formed on a second region above the second conductive type epitaxial layer 120 such that the first conductive type well 150 is aligned horizontally to the second conductive type well 140.

Thereafter, in the step of implanting ions into the active region (e.g., forming regions 180 and 182), a first conductive type ion implantation region 186 can be formed in the upper portion of the first conductive type well 150.

Then, a VDD line 196 connected with the first conductive type ion implantation region 186 in the first conductive type well 150 can be formed, a VSS line 192 connected with the source region 180, transistor gate 170, and second conductive type implantation region 184 can be formed, and a PAD 195 connected with the drain region 182 can be formed.

According to the ESD protection device and the method for manufacturing the same of the embodiment, a part used as the ESD device is electrically isolated, so that performance of an NPN device can be inhibited from being degraded due to reduction in base resistance.

Further, according to an embodiment, a first conductive type well, disposed adjacent the second conductive type well, can be connected with the VDD terminal, so that a parasitic diode is formed between the pad and the VDD terminal. Thus, the parasitic diode can have Ron characteristics superior to those of a P+/Nwell parasitic diode included in the conventional PMOS device, improving ESD properties.

Furthermore, according to an embodiment, properties of an ESD clamp device can be inhibited from being degraded in the 0.13 μm or less CIS process. Moreover, the electrical properties of an NMOS device may not vary even if the Deep NWELL process is supplemented, so that the conventional I/O library can be utilized. In addition, the Ron characteristics of the parasitic diode can be improved due to formation of the guard-ring diode.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An electro-static discharge protection device comprising:
a second conductive type epitaxial layer on a substrate;
a first conductive type deep well on the second conductive type epitaxial layer;
a second conductive type well on the first conductive type deep well;
a plurality of active regions defined by a plurality of isolation layers above the second conductive type epitaxial layer; and
a transistor in a first active region of the plurality of active regions and an ion implantation region in a second active region adjacent the first active region of the plurality of active regions, wherein the transistor and the ion implantation region are disposed on the second conductive type well.

2. The electro-static discharge protection device according to claim 1, further comprising:
a first conductive type well on the first conductive type deep well, the first conductive type well being aligned horizontally to the second conductive type well;
a first conductive type ion implantation region in the first conductive type well; and
a VDD line connected with the first conductive type ion implantation region in the first conductive type well.

3. The electrostatic discharge protection device according to claim 2, wherein the second conductive type epitaxial layer has a total thickness of about 4 μm or less and the first conductive type deep well is provided in the second conductive type epitaxial layer with a thickness of about 1 μm to about 2 μm.

4. The electro-static discharge protection device according to claim 2, wherein the first conductive type deep well has a dopant concentration of about 1×10¹⁷/cm³ to about 1×10¹⁸/cm³.

5. The electro-static discharge protection device according to claim 1, wherein the second conductive type epitaxial layer has a total thickness of about 4 μm or less and the first conductive type deep well is provided in the second conductive type epitaxial layer to have a thickness of about 1 μm to about 2 μm.

6. The electro-static discharge protection device according to claim 1, wherein the first conductive type deep well has a dopant concentration of about 1×10¹⁷/cm³ to about 1×10¹⁸/cm³.

7. The electro-static discharge protection device according to claim 1, wherein the transistor comprises a gate electrode, a first conductive type source region, and a first conductive type drain region, the device further comprising:
a VSS line connected with the first conductive type source region, the ion implantation region, and the gate electrode; and
a PAD connected with the first conductive type drain region.

8. The electro-static discharge protection device according to claim 1, wherein the ion implantation region comprises a second conductive type ion implantation region, wherein the transistor comprises a first conductive type source region and a first conductive type drain region.

9. A method for manufacturing an electro-static discharge protection device, the method comprising:
forming a second conductive type epitaxial layer on a substrate;
forming a second conductive type well on a first region of the second conductive type epitaxial layer;
forming a first conductive type deep well between the second conductive type epitaxial layer and the second conductive type well;
defining a plurality of active regions by forming a plurality of isolation layers on the second conductive type epitaxial layer; and
forming a transistor in one of the plurality of active regions.

10. The method according to claim 9, further comprising:
forming a first conductive type well on a second region of the second conductive type epitaxial layer such that the first conductive type well is aligned horizontally to the second conductive type well;
forming a first conductive type ion implantation region in the first conductive type well; and
forming a VDD line connected with the first conductive type ion implantation region in the first conductive type well.

11. The method according to claim 10, wherein forming the transistor comprises implanting first conductive type dopants to form a source region and drain region.

12. The method according to claim 11, wherein the first conductive type ion implantation region, the source region, and the drain region are simultaneously formed.

13. The method according to claim 9, wherein the forming of the first conductive type deep well is performed after the forming of the second conductive type well.

14. The method according to claim 9, wherein the forming of the first conductive type deep well is performed before the forming of second conductive type well.

15. The method according to claim 9, wherein the second conductive type epitaxial layer is formed to a thickness of about 4 μm or less, and the first conductive type deep well is formed in the second conductive type epitaxial layer to have a thickness of about 1 μm to about 2 μm.

16. The method according to claim 9, wherein the first conductive type deep well is formed by implanting phosphorus (P) with energy of about 1.0 MeV to about 2.0 MeV.

17. The method according to claim 9, wherein forming the first conductive type deep well comprises implanting first conductive type ions at a dose of about 1.0×10¹³/cm² to about 5×10¹³/cm².

18. The method according to claim 9, further comprising forming a second conductive type ion implantation region in the second conductive type well in another one of the plurality of active regions that is adjacent the one in which the transistor is formed.

19. The method according to claim 18, further comprising:
forming a VSS line connected with the second conductive type ion implantation region and a gate electrode and source region of the transistor; and
forming a PAD connected with a drain region of the transistor.
